(19) United States
(12) Patent Application Publication
(10) Pub. No.: US 2009/0206480 A1
(43) Pub. Date: Aug. 20, 2009

(54) FABRICATING LOW COST SOLDER BUMPS ON INTEGRATED CIRCUIT WAFERS

(75) Inventor: Ken Lam, Colorado Springs, CO (US)

Correspondence Address: FISH & RICHARDSON P.C., PO BOX 1022, MINNEAPOLIS, MN, 55440-1022, US

(73) Assignee: ATMEL CORPORATION, San Jose, CA (US)

(21) Appl. No.: 12/034,308

(22) Filed: Feb. 20, 2008

(51) Int. Cl. H01L 23/52; H01L 21/44

(52) U.S. Cl. 257/738; 438/617; 257/E23.141; 257/E21.476

(57) ABSTRACT

A low cost method of forming solder bumps on an integrated circuit (IC) wafer includes depositing solder directly onto stud bumps formed on bond pads of the IC wafer. In some implementations, stud bumps are formed on the IC wafer by performing wire ball-bonding onto metal bond pads of the wafer. Photodefinable solder mask material is applied to the wafer and cured. The photodefinable solder mask material is exposed to form open solder mask areas at the metal bond pad areas. Solder paste is applied into the open solder mask areas. Reflowing the solder paste on the wafer forms solder bumps that wet to the stud bumps. The solder mask is then stripped from the wafer. Other processes (e.g., a wave-soldering machine, stencil or screen printing process) can also be used to wet solder onto stud bumps to form solder bumps.

### TECHNICAL FIELD

This subject matter is generally related integrated circuit (IC) wafer processing.

### BACKGROUND

Wafer-level packaging techniques can include packaging, testing, and performing burn-in operations prior to singulation of the wafer into individual IC chips. During singulation, a dicing machine saws the wafer along scribe lines to separate the individual IC chips. Once an IC chip has been singulated, the IC chip can be mounted on a printed circuit board (PCB).

A typical IC chip uses metal bond pads rather than wires or pins for mounting. The bond pads can be etched or printed onto the wafer, typically along the edges of the package on the face or circuit side of the IC chip. In some implementations, Input/Output (I/O) pads are electrically connected to the bond pads of the IC chip. A redistribution layer (RDL) includes metal lines that can relocate the signals provided by the bond pads to desired locations within the IC chip. Solder bumps can be attached to the I/O pads to facilitate assembly onto PCBs.

Conventional solder bump fabrication techniques involve vacuum deposition, photolithographic, and wet chemical etching processes to form an under bump metal (UBM) layer onto which solder paste or solder plating processes can be used to form the solder bumps.

Vacuum deposition processes and equipment are expensive to purchase, facilitate and maintain. Moreover, wafer bumping with thin-film UBM processes can be costly. Photomask sets are required to define the UBM geometries and locations and, once designed and tooled, cannot be changed. Similarly, the plating equipment, facilitation, maintenance and bath chemistry maintenance involved in electroless plating processes can be costly. Additionally, electroless plating processes are often sensitive to variations in the metal bond pad metallurgy (e.g., aluminum) which can cause plating deposition issues. Therefore, an etching evaluation step is typically performed on each new product at a cost to the customer.

Another shortfall related to the electroless plating UBM process is that the UBM metal can plate onto the backside of the wafer. As a result, the wafer backside may need to be coated with a plating resist and then stripped post UBM deposition. The coating and stripping steps add cost and process lead time.

Both the thin-film UBM process and the electroless plating UBM deposition process typically require wafer thicknesses in excess of 20 mils to prevent wafer breakage during processing. A post-bumping wafer grind step, in many cases, is therefore needed to reduce the wafer depth to the final silicon thickness product requirement. In some circumstances, the final wafer thickness is limited by the solder-bumping process (e.g., about 7 mils) due to the grinding process constraints.

### SUMMARY

A low cost method of forming solder bumps on an IC wafer includes depositing solder directly onto stud bumps formed on bond pads of the IC wafer. In one implementation, stud bumps are formed on the IC wafer by performing wire bonding (e.g., ball or wedge bonding) onto bond pads of the wafer. Photodefinable solder mask material is applied to the wafer and cured. The photodefinable solder mask material is exposed to form open solder mask areas at the metal bond pad areas. Solder paste is applied into the open solder mask areas. Reflowing the solder paste on the wafer forms solder bumps that wet to the stud bumps. The solder mask is then stripped from the wafer.

In another implementation, stud bumps are formed on a wafer by performing wire bonding onto bond pads, applying solder paste onto the stud bumps and reflowing the solder past to form solder bumps which wet to the stud bumps. Optionally, a polymer or other protective layer can be applied to the wafer to protect exposed bond pads.

In another implementation, stud bumps are formed on a wafer by performing wire bonding onto bond pads and passing the wafer through a wave-soldering machine to form solder bumps on the stud bumps.

The simplicity of the disclosed processes provide many advantages, including a lowering of overall product cost when compared with conventional deposited and electroless plated UBM processes. Some examples of cost savings include but are not limited to: a) lower equipment costs and facilitation costs when compared to vacuum deposition equipments, wet-etch lines and plating lines; b) no plating or etching chemical analysis and disposal costs; c) no UBM mask design and mask fabrications costs; d) no repassivation layer costs to “re-shape” the passivation opening; e) no “etch-text” costs as necessary in the electroless UBM process; f) no “full-cassette” charges as necessary in the electroless UBM process; and g) no wafer backside protection layer costs as necessary in the electroless UBM process.

The disclosed processes also provide more flexible changes. Since a wire bonder is used to form the stud bumps on an IC wafer, any changes (e.g., bump pattern, delete bump locations) involve simple changes in wire bonding software which is relatively easy and fast. If using conventional vacuum deposition masks, a new mask set has to be designed and fabricated which can be costly and is often associated with a long lead time.

The disclosed processes also provide higher reliability. The stud bump, which acts as the UBM has a thickness in the range of about 50 microns. The vacuum deposited UBM has a thickness in the 2 micron range and the electro plated UBM thickness can go up to about the 5 micron range. Theoretically, the stud stump UBM has the longest UBM consumption life.

The disclosed processes provide a thin bumped-wafer product. Currently, both vacuum deposited or electroless plated UBM processes require wafer thicknesses in the 20 mil range to prevent breakage during bumping process. If the final product requirement requires thinner wafer thickness, a post-bumping wafer back-grind step can be performed. Due to the presence of solder bumps on the wafer, the current industry bumped-wafer, back-grind capability is at about 7 mils. The wire bonding process can perform bonding on wafers of low thickness. This allows the wafers to be back-grinded to lower than about 7 mils (e.g., about 4 mils), and then processed through a wire bonder to form the stud bump UBM. Wafer thicknesses of lower than about 4 mils can be fabricated.

### DESCRIPTION OF DRAWINGS

FIG. 1 illustrates an example IC package include an IC chip bonded to a substrate or other IC chip using solder bumps which can be fabricated in accordance with processes described in reference to FIGS. 2-4.

FIGS. 2A-2F illustrate a first example wafer-level process for forming solder bumps on metal stud bumps on an IC wafer.

FIGS. 3A-3D illustrate a second example wafer-level process for forming solder bumps on metal stud bumps on an IC wafer.

FIGS. 4A-4C illustrate a third example wafer-level process for forming solder bumps on metal stud bumps on an IC wafer.

### DETAILED DESCRIPTION

### Example IC Package Using Solder Bumps with Stud Stumps

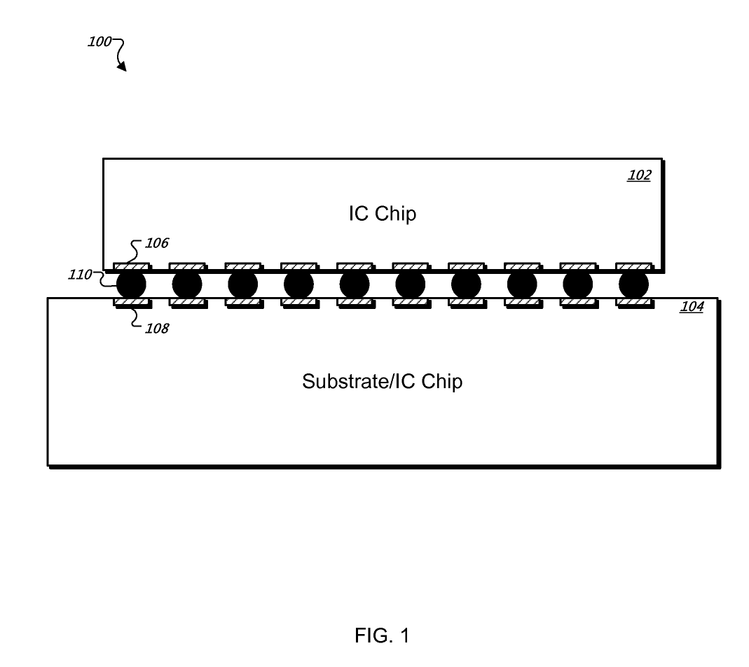

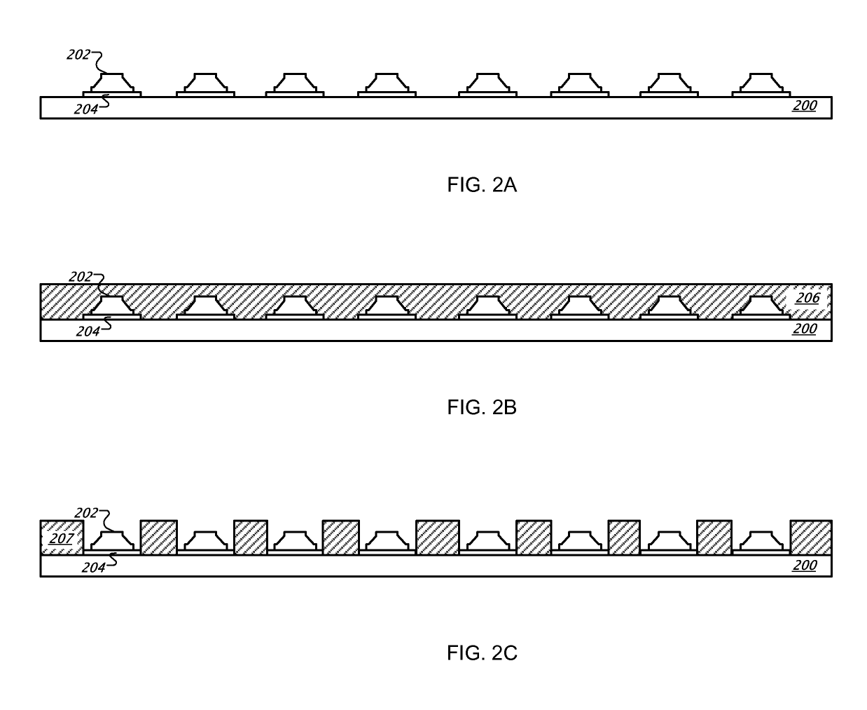

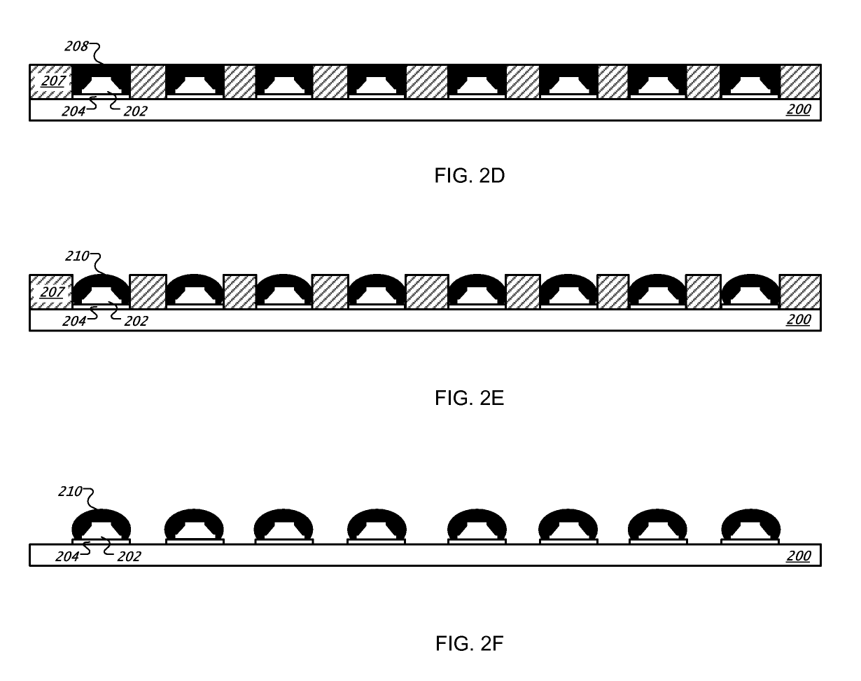

FIG. 1 illustrates an example IC package 100 including IC chip 102 bonded to substrate 104 using solder bumps 110 which can be fabricated in accordance with processes described in reference to FIGS. 2-4. IC package 100 can be formed using a flip-chip method of interconnection where solder bumps 110 electrically interconnect IC chip 102 to substrate 104 or sometimes to another IC chip.

Solder bumps 110 are small spheres of solder (solder balls) that can be bonded to contact areas or metal (e.g., aluminum) bond pads 106 formed on a face (circuit side) of IC chip 102 during wafer fabrication, and subsequently face-down bonded with substrate 104. The length of electrical connections between IC chip 102 and substrate 104 can be minimized by: (a) forming solder bumps 110 on bond pads 106; (b) flipping IC chip 102 face-down; (c) aligning solder bumps 110 with bond pads 108 on substrate 104; and (d) reflowing solder balls 110 in a furnace to establish bonding between IC chip 102 and substrate 104. This method can provide electrical connections with minute parasitic inductances and capacitances. IC package 100 can be used in a variety of technologies, such as 3D-VLSI technology.

A process to form low cost sold bumps 110 on IC wafers will now be described in reference to FIGS. 2A-2F, where solder is deposited directly onto metal stud bumps formed on metal bond pads on an IC wafer.

### First Example Process for Forming Solder Bumps on Stud Bumps

FIGS. 2A-2F illustrate a first example wafer-level process for forming solder bumps on metal stud bumps (e.g., copper, aluminum) of an IC wafer. Referring to FIG. 2A, in some implementations, IC wafer 200 includes a number of metal stud bumps 202. The stud bumps 202 can be formed by wire ball-bonding onto metal bond pads 204 of wafer 200. Ball bond wires (e.g., copper or gold) can be formed on metal bond pads 204 using standard ball-bonding processes.

After forming wire ball bonds on metal bond pads 204, the wires can be cut directly above the ball bonds, leaving metal stud bumps 202. In one example, an electronic flame-off (EFO) can be set to cut the wires directly above the ball bonds to produce stud bumps 202. The size of stud bumps 202 depends, in part, upon the gauge of wire used. For example, the thickness of the stud bumps 202 can be in a range of about 50 microns depending upon the gauge of the wire. In comparison, a typical vacuum-deposited UBM may have a thickness of up to about 2 microns and a typical electroless plated UBM may have a thickness of up to about 5 microns. Theoretically, stud bumps 202 provide a larger surface for a solder ball to adhere to and have a longer consumption life than conventional UBM techniques.

Referring to FIG. 2B, a layer of photodefinable solder mask material 206 is applied over stud bumps 202 on wafer 200. In some implementations, a liquid photoimageable solder mask (LPSM) or a dry film photoimageable solder mask (DFSM) can be applied to wafer 200 using silk screening, spraying, or laminating processes. Upon application, photodefinable solder mask material 206 can be thermally cured.

Referring to FIG. 2C, photodefinable material 206 can be developed out at bond pads 204, exposing stud bumps 202 on wafer 200. Regions 207 of photodefinable solder mask material remain between stud bumps 202.

Referring to FIG. 2D, exposed areas between regions 207 of photodefinable solder mask material can be filled with solder paste 208 (e.g., a mixture of solder materials and flux). In some implementations, solder paste 208 can be applied using a squeegee printing process.

Referring to FIG. 2E, solder paste 208 can be reflowed so that solder paste 208 wets to stud bumps 202, forming solder bumps 210. After solder bumps 210 are formed, as shown in FIG. 2F, regions 207 of photodefinable material can be stripped from wafer 200, leaving solder bumps 210. Optionally, a polymer layer can be applied to wafer 200 to protect exposed portions of bond pads 204. At this point, individual IC chips can be singulated from wafer 200.

If the desired bump pattern changes at a future time (e.g., deletion of one or more bumps, relocation of bumps), then the wire-bonding processes can be easily changed to allow solder bumps 210 to be relocated. Thus using the wire ball-bonding process to form stud bumps 202 allows for quick and inexpensive changes to semiconductor manufacturing processes as opposed to conventional UBM methods.

### Second Example Process for Forming Solder Bumps on Stud Bumps

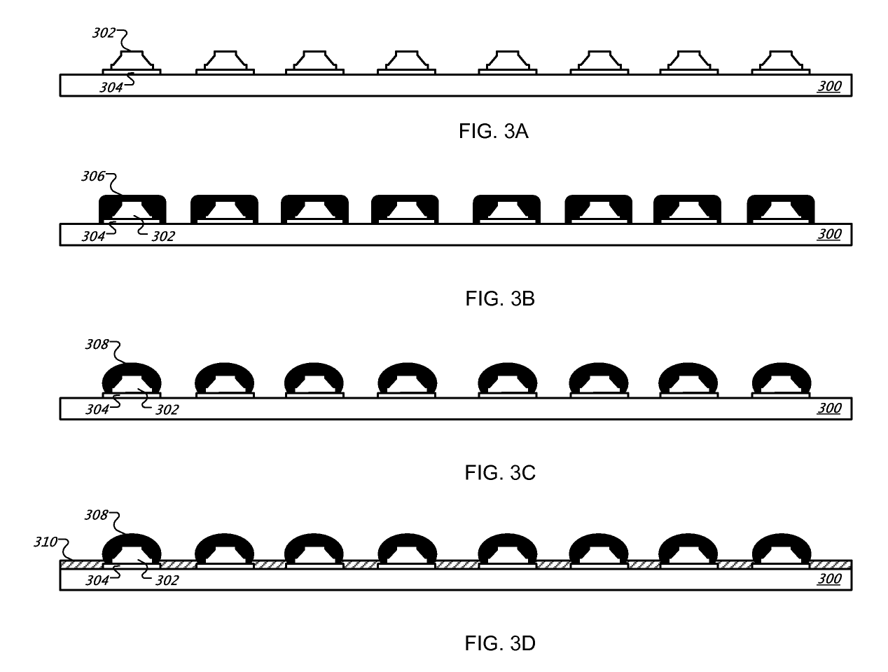

FIGS. 3A-3D illustrate a second alternative example wafer-level process for forming solder bumps on metal stud bumps on an IC wafer. Referring to FIG. 3A, stud bumps 302 are formed on bond pads 304 using wire ball-bonding in the manner described in FIG. 2A. Once stud bumps 302 have been formed, as shown in FIG. 3B, solder paste 306 can be applied to stud bumps 302 using a stencil or screen printing process. Solder paste 306 can then be reflowed. The reflowing wets solder paste 306 to stud bumps 302, forming solder bumps 308, as shown in FIG. 3C. Optionally, polymer layer 310 can be applied to wafer 300, as shown in FIG. 3D. Polymer layer 310 or other protective material can be used to protect exposed portions of bond pads 304.

### Third Example Process For Forming Solder Bumps on Stud Bumps

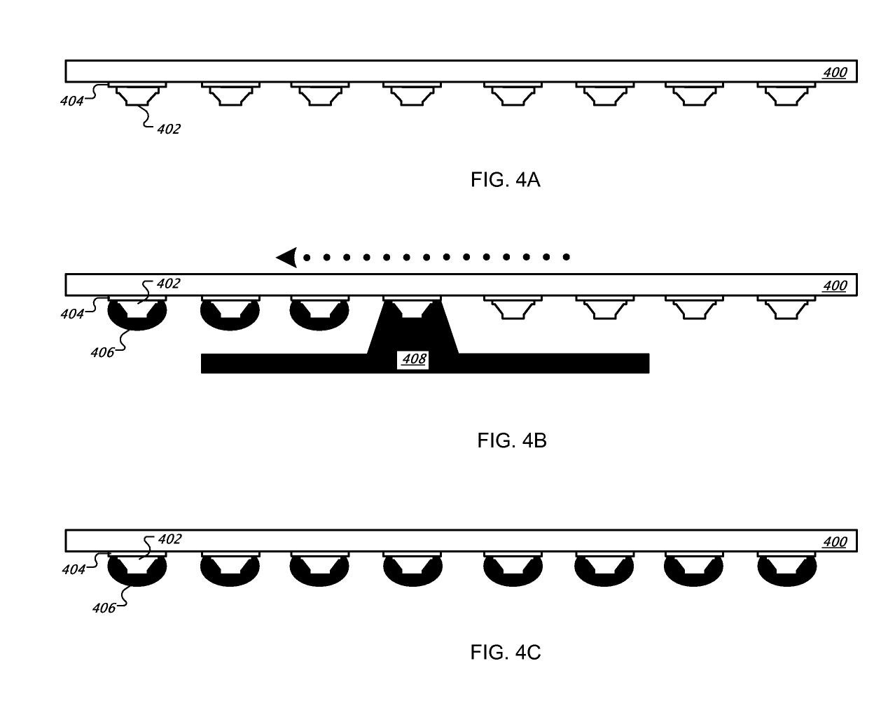

FIGS. 4A-4C illustrate a third example wafer-level process for forming solder bumps on metal stud bumps on an IC wafer 400. Note that in FIG. 4A, the wafer 400 is upside down (compared to wafers 200 and 300) to facilitate passing through a wave-soldering machine. Referring to FIG. 4A, stud bumps 402 are formed on bond pads 404 using wire ball-bonding in the manner described in FIG. 2A. Once stud bumps 402 have been formed, as shown in FIG. 4B, solder bumps 406 can be formed on stud bumps 402 by passing wafer 400 through a wave-soldering machine 408. FIG. 2C illustrates wafer 400 with solder bumps 406 formed on stud bumps 402. Optionally, a polymer layer can be applied to wafer 400 (e.g., as shown in FIG. 3D) to protect exposed portions of bond pads 404.

A number of implementations have been described. Nevertheless, it will be understood that various modifications may be made. For example, steps of one or more processes may be combined, deleted, modified, or supplemented to form further processes. As yet another example, the process steps depicted in the figures do not require the particular order shown to achieve desirable results. In addition, other steps may be provided, or steps may be eliminated, from the described processes, and other materials may be added to, or removed from, the described processes. Accordingly, other implementations are within the scope of the following claims.

What is claimed is:

1. A method of forming solder bumps on an integrated circuit wafer, comprising:
forming stud bumps by performing wire bonding onto metal bond pads of the wafer;
applying photodefinable solder mask material on the wafer;
curing the wafer;
exposing the photodefinable solder mask material to form open solder mask areas at the metal bond pad areas;
applying solder paste into the open solder mask areas;
reflowing solder paste on the wafer to form solder bumps that wet to the stud bumps; and
stripping the solder mask from the wafer.

2. The method of claim 1, where the stud bumps are wire ball bonds made of copper or gold wire.

3. The method of claim 2, where forming stud bumps further comprises:
setting an electronic flame-off to cut the wire directly above the wire ball bond.

4. The method of claim 1, where the solder paste is applied into the open solder mask areas by a squeegee printing process.

5. The method of claim 1, where at least one stud bump has a thickness greater than about 5 microns.

6. The method of claim 1, further comprising:
back-grinding the wafer to less than about 7 mils prior to forming the stud bumps.

7. The method of claim 1, further comprising:
back-grinding the wafer to less than about 4 mils prior to forming the stud bumps.

8. The method of claim 1, further comprising:
sawing the wafer into integrated circuit chips containing solder bumps;
aligning the solder bumps on the chips with contact pads on substrates or other integrated circuit chips; and
bonding together the chips and the substrates or other integrated circuit chips by reflowing the solder bumps.

9. An integrated circuit device, comprising;
a substrate;
an integrated circuit chip; and
solder bumps bonding together the substrate and integrated circuit chip, the solder bumps disposed between metal bonding pads formed on the substrate and the integrated circuit chip, the solder bumps formed on wire bonds.

10. The device of claim 9, where the substrate comprises another integrated circuit chip.

11. The device of claim 9, where the wire bonds are wire ball bonds made of copper or gold wire.

12. A method of forming solder bumps on an integrated circuit wafer, comprising:
forming stud bumps by performing wire bonding onto metal bond pads of the wafer;
applying solder paste on the stud bumps; and
reflowing the solder paste on the wafer to form solder bumps which wet to the stud bumps.

13. The method of claim 12, further comprising:
forming a polymer layer on the wafer after reflowing the solder paste.

14. The method of claims 12, where the stud bumps are wire ball bonds made of copper or gold wire.

15. The method of claim 14, where forming stud bumps further comprises:
setting an electronic flame-off to cut the wire directly above the wire ball bond.

16. The method of claim 12, where the solder paste is applied to the stud bumps by a stencil or a screen printing process.

17. The method of claim 12, where the stud bump has a thickness greater than about 5 microns.

18. The method of claim 12, further comprising:
back-grinding the wafer to less than about 7 mils prior to forming the stud bumps.

19. The method of claim 12, further comprising:
back-grinding the wafer to less than about 4 mils prior to forming the stud bumps.

20. The method of claim 12, further comprising:
sawing the wafer into integrated circuit chips containing the solder bumps;
aligning the solder bumps on the chips with contact pads on substrates or other integrated circuit chips; and
bonding together the chips and the substrates or other integrated circuit chips by reflowing the solder bumps.

21. A method of forming solder bumps on an integrated circuit wafer, comprising:
forming stud bumps by performing wire bonding onto bond pads of the wafer; and
applying solder to the stud bumps using a wave-soldering machine.

22. The method of claims 21, where the stud bumps are wire ball bonds made of copper or gold wire.

23. The method of claim 22, where forming stud bumps further comprises:
setting an electronic flame-off to cut the wire directly above the wire ball bond.

24. The method of claim 21, where the stud bump has a thickness greater than about 5 microns.

25. The method of claim 21, further comprising:
back-grinding the wafer to less than about 7 mils prior to forming the stud bumps.

26. The method of claim 21, further comprising:
back-grinding the wafer to less than about 4 mils prior to forming the stud bumps.

27. The method of claim 21, further comprising:
sawing the wafer into integrated circuit chips containing the solder bumps;
aligning the solder bumps on the chips with contact pads on substrates or other integrated circuit chips; and
bonding together the chips and the substrates or other integrated circuit chips by reflowing the solder bumps.
